(19) United States
(12) Patent Application Publication
(10) Pub. No.: US 2013/0223148 A1
(43) Pub. Date: Aug. 29, 2013

(54) NONVOLATILE MEMORY DEVICE AND EMBEDDED MEMORY SYSTEM INCLUDING THE SAME

(71) Applicant: Samsung Electronics Co., Ltd., (US)

(72) Inventors: BoYoung Seo, Suwon-si (KR); YongKyu Lee, Gwacheon-si (KR); HeeSeog Jeon, Suwon-si (KR)

(73) Assignee: Samsung Electronics Co., Ltd., Suwon-si (KR)

(21) Appl. No.: 13/751,786

(22) Filed: Jan. 28, 2013

(30) Foreign Application Priority Data
Feb. 28, 2012 (KR) 10-2012-0020327

(51) Int. Cl. H01L 27/04; G11C 16/14; G11C 16/16

(52) U.S. Cl. CPC H01L 27/04; G11C 16/16; G11C 16/14
USPC 365/185.11; 365/185.14; 257/316

(57) ABSTRACT

Integrated circuit memory devices include an array of nonvolatile memory cells having a plurality of pairs of nonvolatile memory cells therein. The plurality of pairs of nonvolatile memory cells include a first pair of nonvolatile memory cells, which share an erase gate electrode. Each of the nonvolatile memory cells in the first pair of nonvolatile memory cells includes a respective control gate electrode and the shared erase gate electrode extends between the control gate electrodes within the first pair of nonvolatile memory cells. Each of the first pair of nonvolatile memory cells may include a data storage transistor, which has a floating gate electrode therein, and a selection transistor. These transistors may be electrically connected in series and the shared erase gate electrode may extend between the floating gate electrodes.

### REFERENCE TO PRIORITY APPLICATION

A claim for priority under 35 U.S.C. §119 is made to Korean Patent Application No. 10-2012-0020327, filed Feb. 28, 2012, the entire contents of which are hereby incorporated herein by reference.

### FIELD

The inventive concepts described herein relate to a nonvolatile memory device and, more particularly, to an embedded memory system and a nonvolatile memory device included within the embedded memory system.

### BACKGROUND

A semiconductor memory device is typically fabricated using semiconductors such as silicon (Si), germanium (Ge), gallium arsenide (GaAs), indium phosphide (InP), and the like. Semiconductor memory devices are classified into volatile memory devices and nonvolatile memory devices.

The volatile memory devices may lose stored contents at power-off. The volatile memory devices include a static RAM (SRAM), a dynamic RAM (DRAM), a synchronous DRAM (SDRAM), and the like. The nonvolatile memory devices may retain stored contents even at power-off. The nonvolatile memory devices include a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), a ferroelectric RAM (FRAM), and the like.

An embedded memory system may use a nonvolatile memory device which includes memory cells each formed of a cell transistor and a selection transistor.

### SUMMARY

Integrated circuit memory devices according to embodiments of the present invention include an array of nonvolatile memory cells having a plurality of pairs of nonvolatile memory cells therein. According to some embodiments of the invention, the plurality of pairs of nonvolatile memory cells include a first pair of nonvolatile memory cells, which share a common erase gate electrode. Each of the nonvolatile memory cells in the first pair of nonvolatile memory cells may include a respective control gate electrode and the shared erase gate electrode may extend between the control gate electrodes within the first pair of nonvolatile memory cells. According to additional embodiments of the invention, each of the first pair of nonvolatile memory cells may include a data storage transistor, which has a floating gate electrode therein, and a selection transistor. In particular, the selection transistor and the data storage transistor within a nonvolatile memory cell may be electrically connected in series. The gate electrodes of the selection transistors can be electrically coupled to respective word lines and each of the data storage transistors within the first pair may include a respective one of the control gate electrodes. In addition, the shared erase gate electrode can extend between the floating gate electrodes within the first pair of nonvolatile memory cells.

According to additional embodiments of the invention, control logic is provided, which is configured to support a page erase operation. During the page erase operation, unequal voltages are applied to the control gate electrodes of the first pair of nonvolatile memory cells to thereby selectively erase one of the first pair of nonvolatile memory cells, but not the other.

A nonvolatile memory device according to additional embodiments of the invention includes a block of nonvolatile memory cells having a plurality of pairs of nonvolatile memory cells therein. The plurality of pairs of nonvolatile memory cells include a first pair of nonvolatile memory cells, which share a first erase gate electrode within a first sector of the block, and a second pair of nonvolatile memory cells, which share a second erase gate electrode within a second sector of the block. A sector selecting circuit is provided, which is electrically connected to the first and second erase gate electrodes, an erase gate line and first and second sector selection lines. Control logic is also provided, which is electrically coupled to the erase gate line and the first and second sector selection lines. This control logic is configured to support a multi-sector page erase operation by driving the first and second sector selection lines with signals that cause the sector selecting circuit to electrically connect the first and second erase gate electrodes to the erase gate line. This control logic is further configured to support a single-sector page erase operation by driving the first and second sector selection lines with signals that cause the sector selecting circuit to electrically connect the erase gate line one-at-a-time to the first and second erase gate electrodes. In particular, the sector selecting circuit may include first and second PMOS transistors having first and second gate electrodes, respectively, which are electrically connected to the first and second sector selection lines, respectively, and the control logic.

According to additional embodiments of the invention, each of the nonvolatile memory cells in the first pair of nonvolatile memory cells may include a respective control gate electrode, and the shared first erase gate electrode may extend between the control gate electrodes within the first pair of nonvolatile memory cells. In particular, each of the nonvolatile memory cells in the first pair of nonvolatile memory cells may include a data storage transistor, which has a floating gate electrode therein, and a selection transistor. In particular, the selection transistor and the data storage transistor within one of the first pair of nonvolatile memory cells may be electrically connected in series and a gate electrode of the selection transistor may be electrically coupled to a respective word line.

### BRIEF DESCRIPTION OF THE DRAWINGS

The above and other objects and features will become apparent from the following description with reference to the following figures, wherein like reference numerals refer to like parts throughout the various figures unless otherwise specified.

FIG. 1 is a block diagram schematically illustrating a nonvolatile memory device according to an embodiment of the inventive concept.

FIG. 2 is a circuit diagram schematically illustrating a memory cell array in FIG. 1.

FIG. 3 is a cross-sectional view of a double memory cell structure in FIG. 2.

FIGS. 4 to 6 are diagrams describing a program operation of a nonvolatile memory device according to an embodiment of the inventive concept.

FIGS. 7 to 9 are diagrams describing an erase operation of a nonvolatile memory device according to an embodiment of the inventive concept.

FIGS. 10 to 12 are diagrams describing an erase operation performed by a page unit.

FIG. 13 is a circuit diagram illustrating a memory cell array in FIG. 1.

FIG. 14 is a diagram illustrating a bias condition of a memory cell array in FIG. 13 when an erase operation is performed by a sector unit.

FIG. 15 is a diagram illustrating a sector to be erased according to a bias condition in FIG. 14.

FIGS. 16 and 17 are diagrams describing an erase operation according to another embodiment of the inventive concept.

FIG. 18 is a diagram schematically illustrating a memory cell array according to still another embodiment of the inventive concept.

FIG. 19 is a block diagram schematically illustrating an embedded system according to an embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the scope of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

The term “selected line” or “selected lines” may be used to indicate a line or lines, associated with a memory cells to be programmed or erased, from among a plurality of lines. The term “unselected line” or “unselected lines” may be used to indicate a line or lines, associated with a memory cells not to be programmed or erased, from among a plurality of lines. The term “selected memory cell” or “selected memory cells” may be used to indicate a memory cell or memory cells to be programmed or erased from among a plurality of memory cells. The term “unselected memory cell” or “unselected memory cells” may be used to indicate the remaining memory cell or memory cells other than the selected memory cell or memory cells.

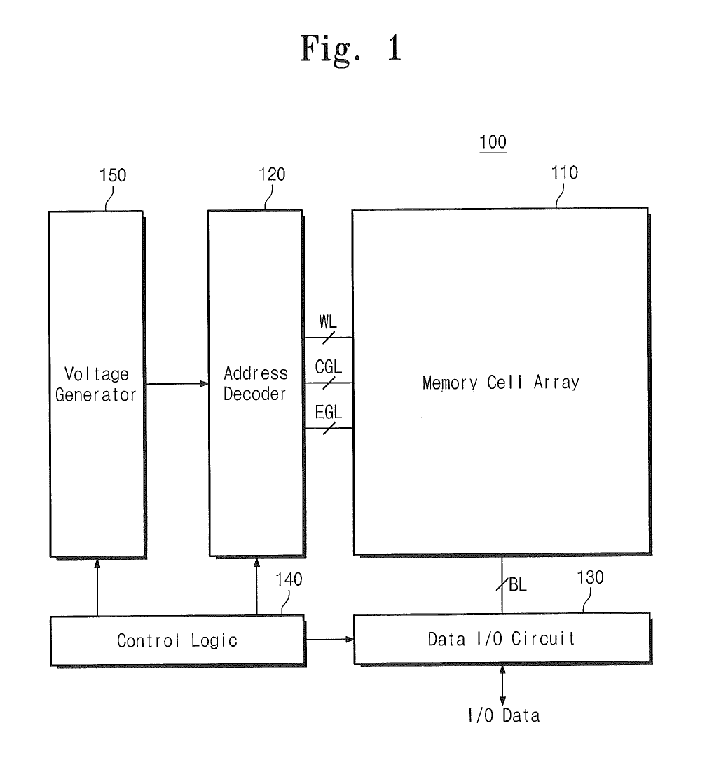

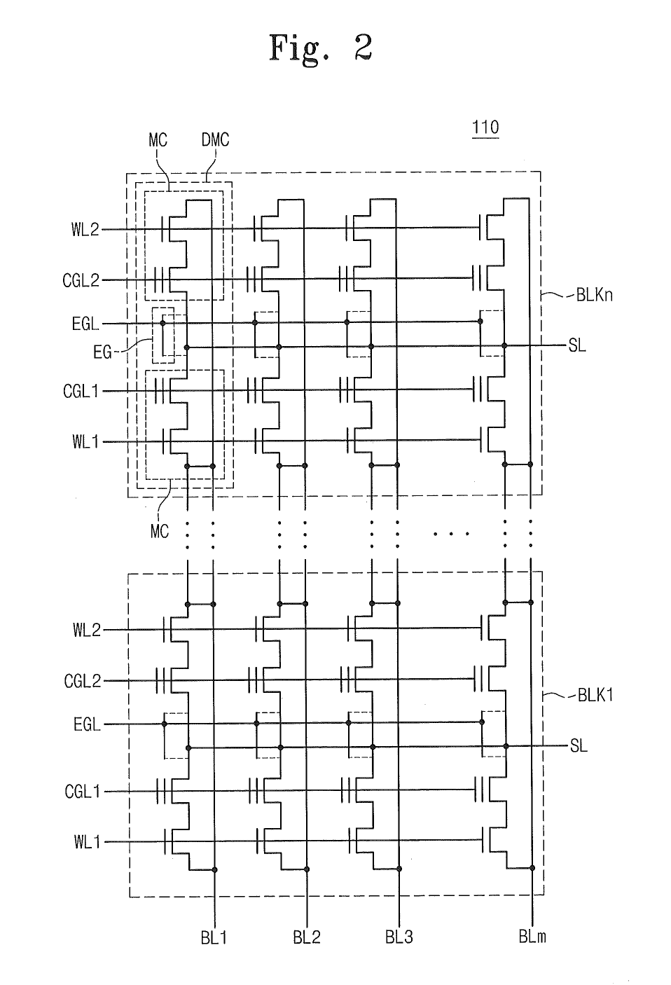

FIG. 1 is a block diagram schematically illustrating a nonvolatile memory device according to an embodiment of the inventive concept. Referring to FIG. 1, a nonvolatile memory device 100 may include a memory cell array 110, an address decoder 120, a data input/output circuit 130, control logic 140, and a voltage generator 150. The memory cell array 110 may include a plurality of memory cells. A memory cell may store one data bit, which is referred to as a single level cell (SLC). A memory cell may store two or more bits of data, which is referred to as a multi-level cell (MLC). Each memory cell may include a cell transistor and a selection transistor. Two memory cells being adjacent may share an erase gate. During an erase operation, charges of a memory cell may be collected at an erase gate by the F-N tunneling. The memory cell array 110 will be more fully described with reference to FIG. 2.

The address decoder 120 may be connected to the memory cell array 110 via word lines WL, control gate lines CGL, and erase gate lines EGL. The address decoder 120 may select a word line, a control gate line, and an erase gate line of a memory cell to be selected in response to address information. The address decoder 120 may transfer various voltages from the voltage generator 150 to the selected word line, control gate line, and erase gate line.

The data input/output circuit 130 may be connected to the memory cell array 110 via bit lines BL. The data input/output circuit 130 may receive data from an external device to store it at the memory cell array 110. The data input/output circuit 130 may read data from the memory cell array 110 to transfer it to the external device. In example embodiments, the data input/output circuit 130 may include well-known elements such as a column selection gate, a page buffer, a data buffer, and the like. In other example embodiments, the data input/output circuit 130 may include well-known elements such as a column selection gate, a write driver, a sense amplifier, a data buffer, and the like.

The control logic 140 may control an overall operation of the nonvolatile memory device 100, based on an erase procedure according to an embodiment of the inventive concept. For example, to erase two pages of data at a time, the control logic 140 may apply the same voltage to control gate lines of memory cells sharing an erase gate. In other example embodiments, the control logic 140 may apply different voltages to control gate lines of memory cells sharing an erase gate to perform an erase operation by a page unit. The voltage generator 150 may generate a DC voltage under the control of the control logic 140. The voltage generator 150 may generate overall DC voltages for program and erase operations of the nonvolatile memory device 100 under the control of the control logic 150.

FIG. 2 is a circuit diagram schematically illustrating a memory cell array in FIG. 1. Referring to FIG. 2, a memory cell array 110 may include a plurality of memory cells MC. Each memory cell MC may include a selection transistor and a cell transistor that are connected in series. In each memory cell MC, a gate of a selection transistor may be connected to a word line WL, and a control gate CG of a cell transistor may be connected to a control gate line CGL.

Two adjacent memory cells MC may share an erase gate EG. A memory cell MC, an erase gate EG, and a memory cell MC, which are connected in series, may be referred to as a double memory cell (DMC) structure. One end of the erase gate EG may be connected to an erase gate line EGL, and the other end thereof may be connected to a source line SL. During an erase operation, the erase gate EG may be used to collect electrons of a floating gate of a cell transistor in an adjacent memory cell.

Memory cells connected via the same word line and the same control gate line may constitute a page. With the DMC structure illustrated in FIG, 2, two adjacent pages of memory cells may share erase gates via the same erase gate line EGL. The memory cell array 110 may include a plurality of blocks BLK1 to BLKn, each of which includes two pages sharing erase gates connected via the same erase gate line EGL,

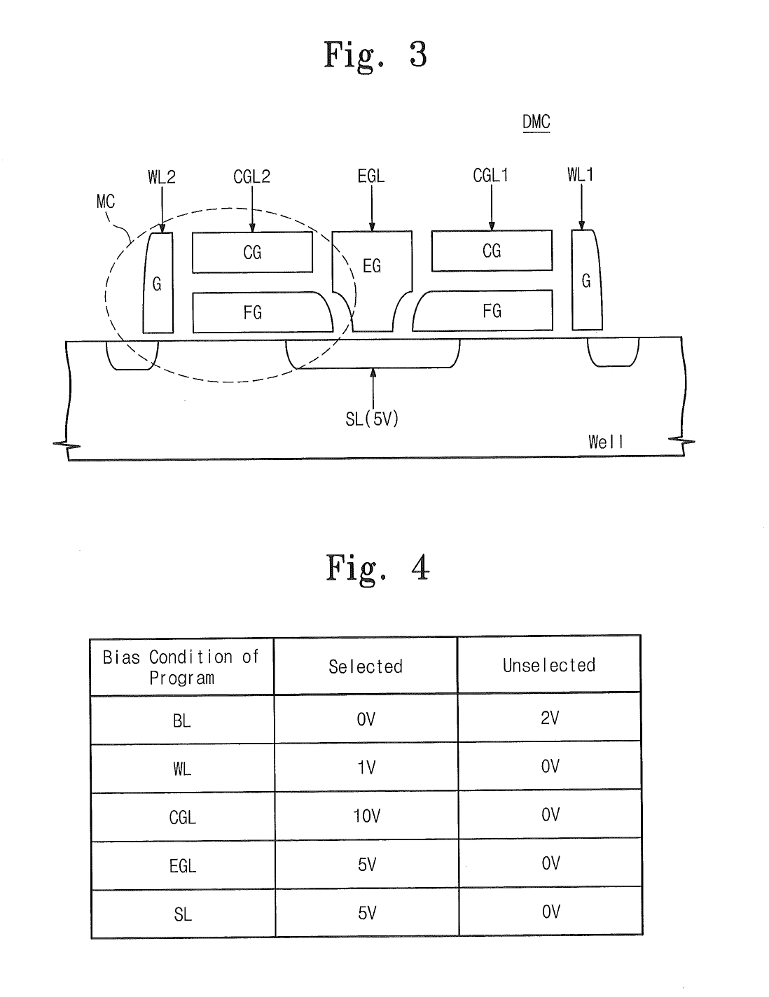

FIG. 3 is a cross-sectional view of a double memory cell structure in FIG. 2. An erase gate EG may be stacked over a well, and pairs of cell and selection transistors may be arranged to be symmetrical on a basis of the erase gate EG. The erase gate EG may be connected to an erase gate line EGL. An n+ doping region may be formed at the well to be partially overlapped with floating gates in adjacent memory cells MC, and may be connected with a source line SL. A cell transistor may be formed between the erase gate EG and a selection transistor, and may include a floating gate FG and a control gate CG sequentially stacked. The control gate CG of the cell transistor may be connected to a control gate line CGL. The selection transistor may be formed at one side of the cell transistor, and may include a gate G. The gate G of the selection transistor may be connected to a word line WL.

FIGS. 4 to 6 are diagrams describing a program operation of a nonvolatile memory device according to an embodiment of the inventive concept. In FIG. 4, there is illustrated a bias condition associated with the case that memory cells of a memory cell array 110 (refer to FIG. 2) are programmed by a page unit. Referring to FIG. 4, a voltage of 0V may be applied to a bit line corresponding to a memory cell to be programmed. A voltage of 1V may be applied to a word line corresponding to a memory cell to be programmed, and a voltage of 10V may be applied to a control gate line CGL corresponding to a memory cell to be programmed. A voltage supplied to the selected word line WL may be referred to as a selection voltage, and a voltage supplied to the selected control gate line CGL may be referred to as a program voltage.

The selection and program voltages illustrated in FIG. 4 may be exemplary, and may be adjusted variously. For example, the selection voltage may be decided to have a voltage level sufficient to turn on a selection transistor of a memory cell MC (refer to FIG. 2), and the program voltage may be decided to have a voltage level sufficient to inject electrodes into a floating gate of the memory cell MC. A voltage of 5V may be supplied to an erase gate line EGL and a source line SL corresponding to the memory cell to be programmed, respectively. However, the inventive concept is not limited thereto. Voltages applied to the erase gate line EGL and the source line SL may be varied variously. The voltages applied to the erase gate line EGL and the source line SL may have the same or similar voltage level such that no voltage difference between the erase gate line EGL and the source line SL exists.

A voltage of 2V may be provided to a bit line BL corresponding to an unselected memory cell. A voltage provided to a bit line BL corresponding to an unselected memory cell may be referred to as a program-inhibit voltage. A word line WL, a control gate line CGL, an erase gate line EGL, and a source line associated with the unselected memory cell may be grounded.

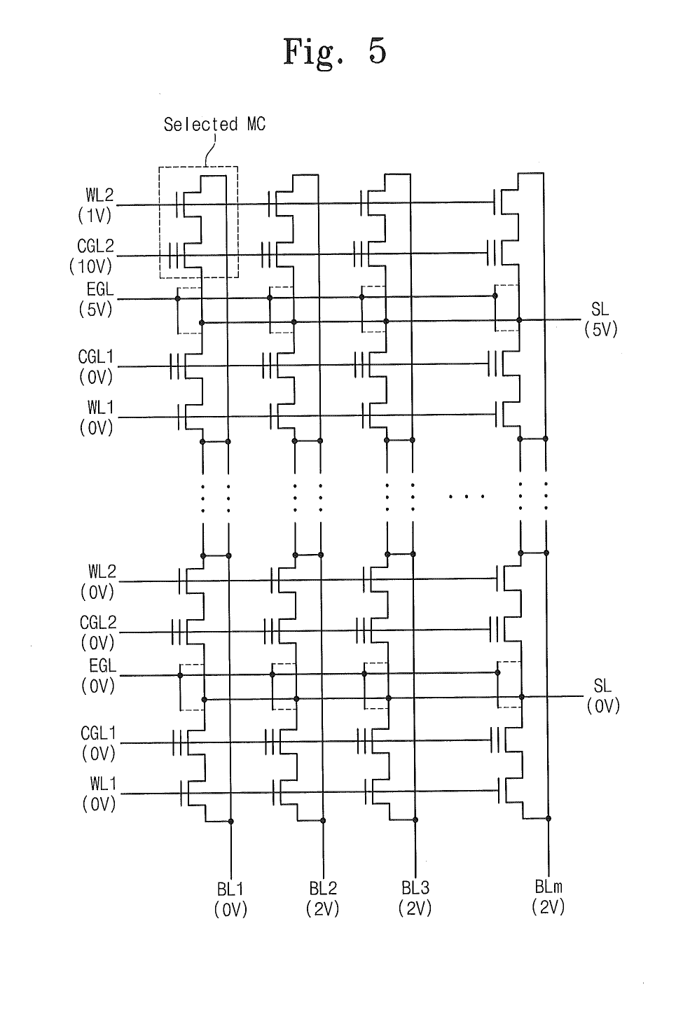

In FIG. 5, there is illustrated a memory cell being programmed according to a bias condition in FIG. 4. For ease of description, it is assumed that there is programmed a memory cell connected to a second word line WL2 and a second control gate line CGL2 in a row direction and to a first bit line BL1 in a column direction. With this assumption, the selection voltage of 1V and the program voltage of 10V may be provided to the second word line WL2 and the second control gate line CGL2 associated with the selected memory cell, respectively. Also, the first bit line BL1 may be grounded, and the same voltage of 5V may be applied to the erase gate line EGL and the source line SL associated with the selected memory cell, respectively. A program-inhibit voltage of 2V may be supplied to bit lines BL2 to BLm of unselected memory cells.

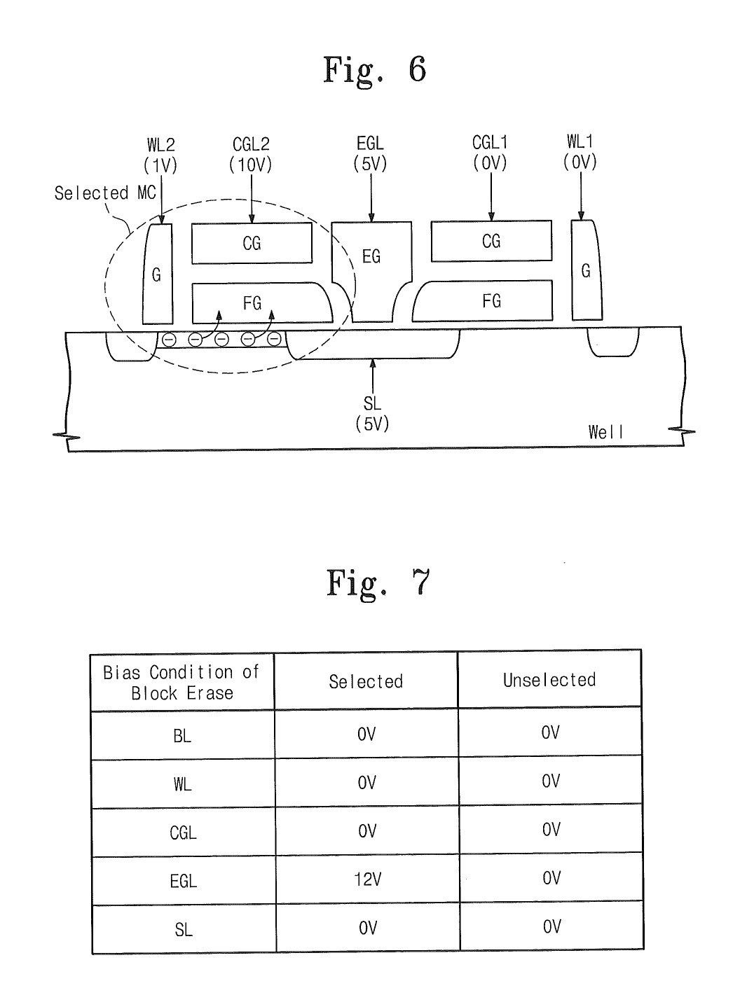

In FIG. 6, there is illustrated a cross-sectional view describing a program operation of a selected memory cell in FIG. 5. Referring to FIG. 6, since the selection voltage of 1V and the program voltage of 10V may be provided to the second word line WL2 and the second control gate line CGL2 associated with the selected memory cell, respectively, a channel may be formed in the well region. Electrons of the channel may be injected into a floating gate FG by the hot carrier scheme. That is, the selected memory cell may be programmed. There are grounded a first word line WL1 and a first control gate line CGL1 of a memory cell sharing the same erase gate EG as the selected memory cell. That is, a memory cell may not be programmed. As a result, during a single memory cell in the illustrated pair may be programmed.

FIGS. 7 to 9 are diagrams describing an erase operation of a nonvolatile memory device according to an embodiment of the inventive concept. In FIG. 7, there is illustrated a bias condition associated with the case that memory cells of a memory cell array 110 (refer to FIG. 2) are erased by a block unit. Referring to FIG. 7, a voltage of 12V may be supplied to an erase gate line EGL of a block to be erased. A voltage supplied to the erase gate line EGL of a block to be erased may be referred to as an erase voltage. The erase voltage may be adjusted variously. For example, the erase voltage may be decided to have a voltage level sufficient to generate the F-N tunneling between a floating gate and an erase gate. Charges may be shifted into the erase gate from the floating gate due to the F-N tunneling. During the erase operation, a voltage of 0V may be applied to the remaining lines other than the erase gate line EGL.

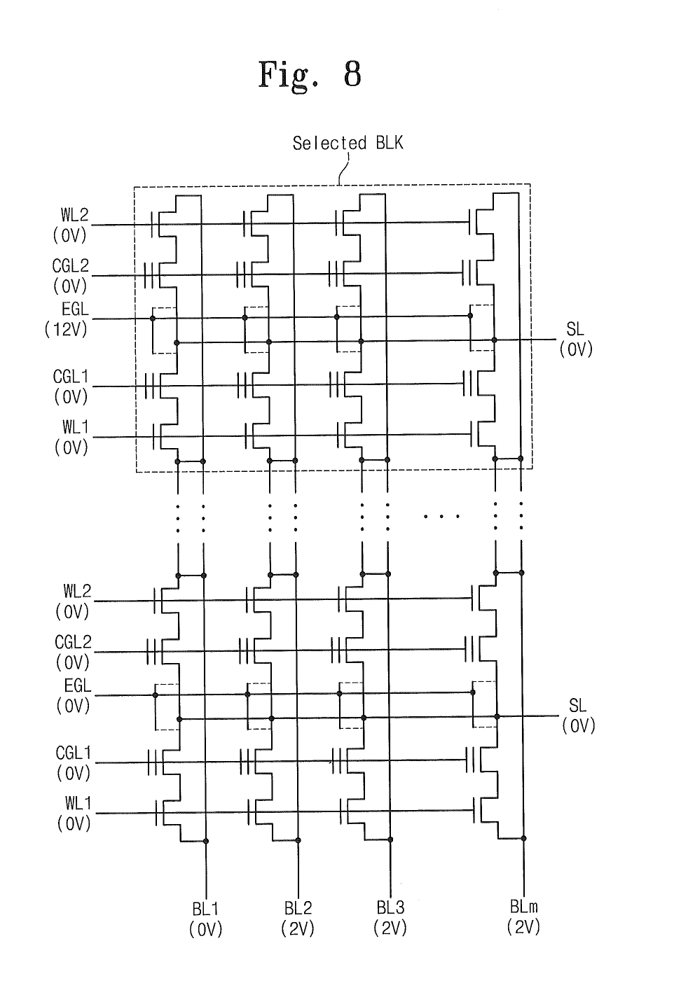

In FIG. 8, there is illustrated a block being erased according to a bias condition in FIG. 7. For ease of description, it is assumed that an nth block is erased. With this assumption, a voltage of 12V may be applied to an erase gate line EGL of a selected block BLKn, and the remaining lines other than the erase gate line EGL may be grounded.

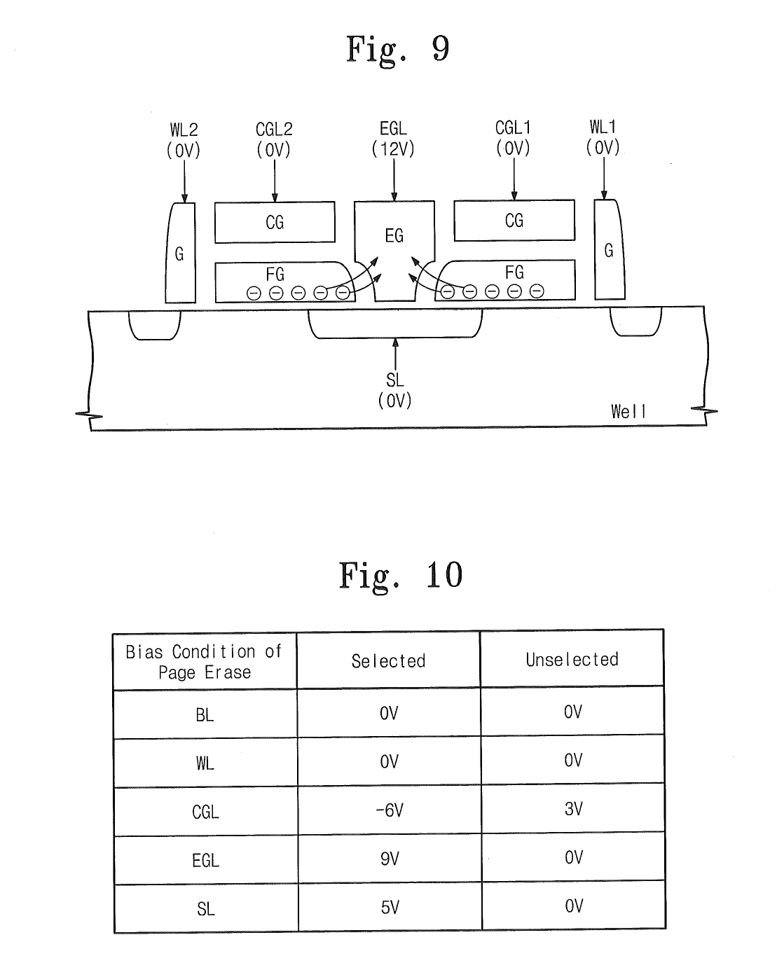

In FIG. 9, there is illustrated a cross-section view describing an erase operation of a selected block in FIG. 7. Referring to FIG. 9, an erase voltage of 12V may be supplied to an erase gate EG of a block to be erased via an erase gate line EGL, and a voltage of 0V may applied to a source via a source line SL. Control gates CG of cell transistors disposed at right and left sides of the erase gate EG may be grounded. Electrons may be shifted into the erase gate EG from the floating gate FG due to the F-N tunneling generated by a potential difference between the floating gate FG and the erase gate EG. That is, memory cells in the selected block may be erased.

As described with reference to FIGS. 7 to 9, an erase operation of a memory cell array 110 in FIG. 2 may be carried out by a block unit. However, the inventive concept is not limited thereto. For example, an erase operation of a memory cell array 110 in FIG. 2 may be carried out by a unit smaller than a block unit. In the event that an embedded device uses a nonvolatile memory device 100 in FIGS. 1 and 2, it may necessitate an erase operation that is performed by a page unit or a byte unit, not a block unit in which two pages are simultaneously erased.

FIGS. 10 to 12 are diagrams describing an erase operation performed by a page unit. In FIG. 10, there is illustrated a bias condition associated with the case that memory cells of a memory cell array 110 (refer to FIG. 2) are erased by a page unit. Referring to FIG. 10, a voltage of 9V may be supplied to an erase gate line EGL corresponding to a page to be erased. Also, a voltage of −6V may be supplied to a control gate line CGL corresponding to a page to be erased. A voltage supplied to the control gate line CGL corresponding to a page to be erased may be referred to as a control gate erase voltage. An erase voltage provided to the selected erase gate line EGL and the control gate erase voltage provided to the selected control gate line CGL may be adjusted variously. For example, the erase voltage and the control gate erase voltage may be decided to have voltage levels sufficient to generate the F-N tunneling between a floating gate FG of a selected memory cell and an erase gate EG. A voltage of 3V may be provided to a control gate line CGL corresponding to a page not to be erased. The voltage provided to the control gate line CGL corresponding to a page not to be erased may be referred to as an erase-inhibit voltage. The erase-inhibit voltage may be adjusted variously. For example, the erase-inhibit voltage may be decided such that no F-N tunneling is generated by a potential difference between a floating gate FG of an unselected memory cell and an erase gate EG. A voltage of 5V may be provided to a source line SL corresponding to a page to be erased, and the remaining lines may be grounded.

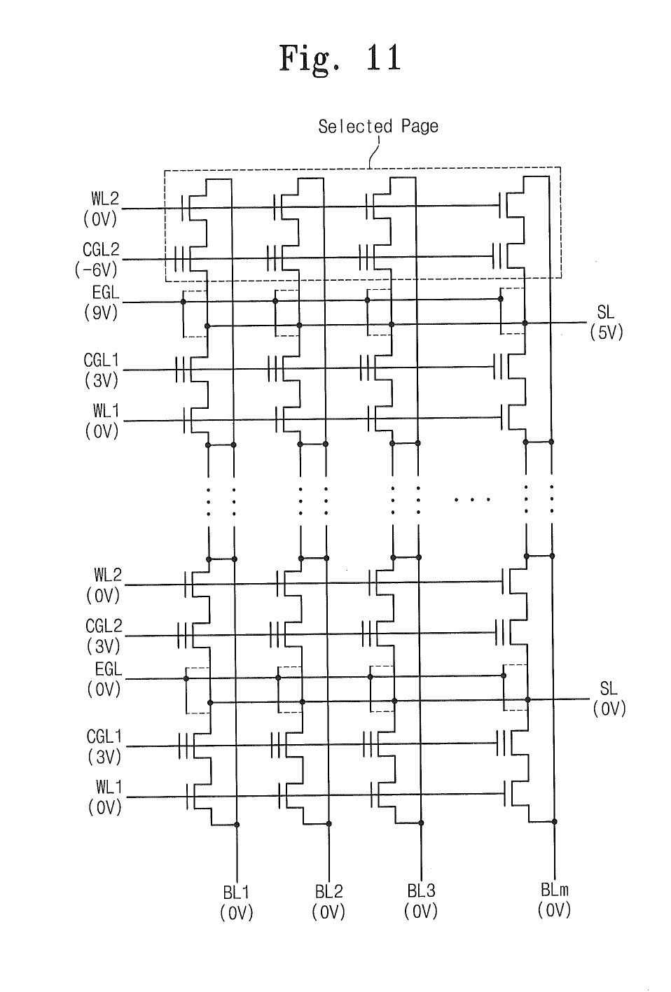

In FIG. 11, there is illustrated a page being erased according to a bias condition in FIG. 10. For ease of description, it is assumed that memory cells connected in common to a second word line WL2 and a second control gate line CGL2 of an nth block BLKn are erased. In this case, an erase voltage of 9V may be applied to an erase gate EG of a selected page via an erase gate line EGL. Also, a control gate erase voltage of −6V may be supplied to the second control gate line CGL2, and an erase-inhibit voltage of 3V may be applied to a first control gate line CGL1 of an unselected page. A voltage of 5V may be applied to a source line SSL of the selected page, and the remaining lines other than the source line SL may be grounded. It is assumed that a voltage of 3V is applied to first and second control gate lines CGL1 and CGL2 of a block BLK1 other than a block BLKn including a selected page. However, the inventive concept is not limited thereto. For example, a voltage of 0V can be applied to the first and second control gate lines CGL1 and CGL2.

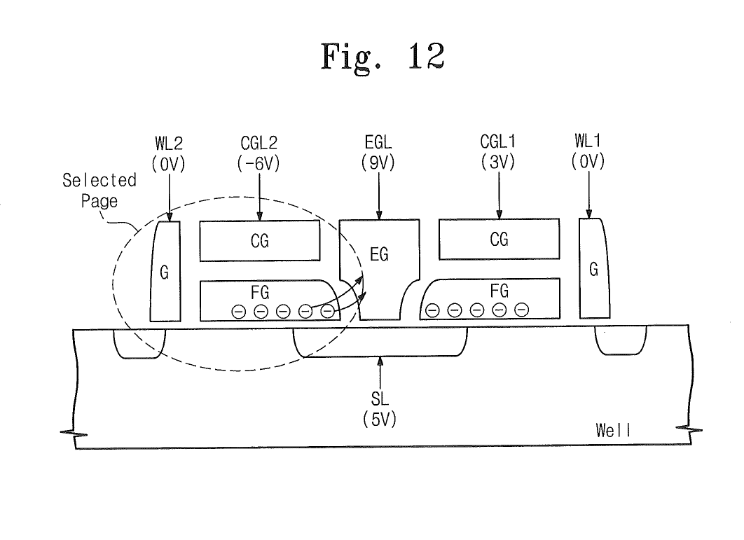

In FIG. 12, there is illustrated a cross-section view describing an erase operation of a selected page in FIG. 11. Referring to FIG. 12, an erase voltage of 9V and a source voltage of 5V may be applied to an erase gate EG and a source, respectively. A control gate erase voltage of −6V may be provided to a control gate corresponding to a selected page via a second control gate line CGL2. A potential difference sufficient to generate the F-N tunneling may be generated between a floating gate FG corresponding to the selected page and an erase gate EG. Charges of the floating gate FG may be shifted into the erase gate EG. That is, an erase operation on the selected page may be performed. An erase-inhibit voltage may be provided to a control gate corresponding to an unselected page via a first control gate line CGL1. In this case, since the erase-inhibit voltage is higher than a voltage for generating the F-N tunneling, an erase operation on an unselected page may not be performed. As a result, an erase operation may be carried out by a page unit.

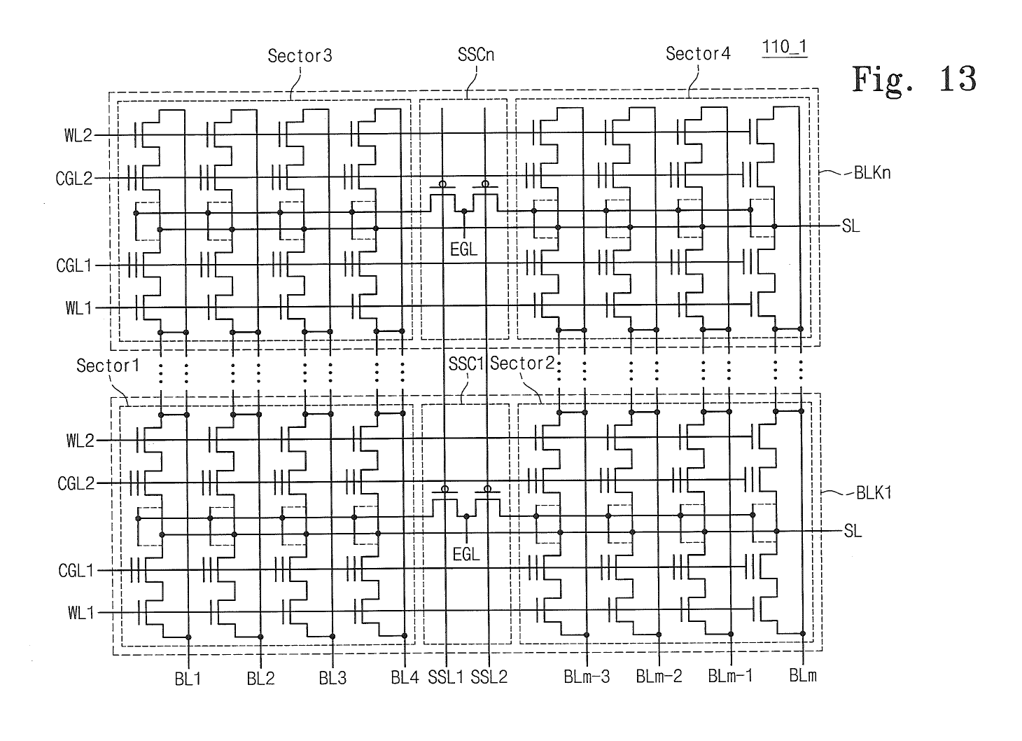

FIG. 13 is a circuit diagram illustrating a memory cell array in FIG. 1. A memory cell array 110_1 in FIG. 13 may be similar to that in FIG. 2. Thus, similar elements may be marked by similar reference numerals. Compared with a memory cell array 110 in FIG. 2, the memory cell array 110_1 in FIG. 13 may further comprise a sector selecting circuit SSC. Each block may include the selector selecting circuit SSC, which is used to divide a corresponding block into a plurality of sectors. Each sector selection circuit SSC may include two PMOS transistors connected in series. One ends of the two PMOS transistors may be connected to an erase gate, respectively. The other ends of the two PMOS transistors may be connected to an erase gate line EGL. The PMOS transistors in each sector selecting circuit SSC may be turned on or off by first and second sector selecting lines SSL1 and SSL2. Thus, an erase voltage may be selectively provided to one of two sectors via the erase gate line EGL according to voltage of the first and second sector selecting lines SSL1 and SSL2. For example, a first block BLK1 may include a first sector selecting circuit SSC1. The first block BLK1 may be divided into a first sector and a second sector by the first sector selecting circuit SSC1. The first sector selecting circuit SSC1 may select one of the first and second sectors in response to voltages of the first and second sector selecting lines SSL1 and SSL2. At this time, an erase voltage may be provided to a selected sector via the erase gate line EGL, so that an erase operation on the selected sector is performed.

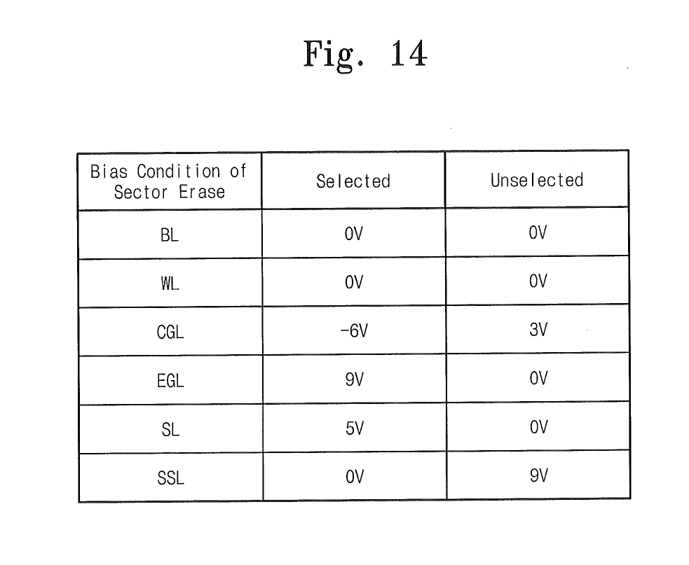

FIG. 14 is a diagram illustrating a bias condition of a memory cell array in FIG. 13 when an erase operation is performed by a sector unit. A bias condition in FIG. 14 may be similar to a bias condition of an erase operation performed by a block unit. Thus, a difference between a block erase operation and a sector erase operation will be focused.

As described in FIG. 13, to perform an erase operation by a sector unit, a memory cell array 110 (refer to FIG. 13) may further comprise a sector selecting circuit SSC and selector selecting lines connected to the sector selecting circuit SSC. A bias condition associated with a sector erase operation in FIG. 14 may further comprise a bias condition of a sector selecting line compared with a bias condition associated with a block erase operation.

When an erase operation is performed by a sector unit, a voltage of 0V may be applied to a sector selecting line SSL corresponding to a selected sector, and a voltage of 9V may be applied to a sector selecting line SSL corresponding to an unselected sector. Herein, a voltage applied to a sector selecting line SSL corresponding to a selected sector may be referred to as a selection sector voltage, and a voltage applied to a sector selecting line SSL corresponding to an unselected sector may be referred to as a non-selection sector voltage. The section sector voltage and the non-selection sector voltage may be adjusted variously. For example, the section sector voltage may be decided to have a voltage level sufficient to turn on a PMOS transistor, and the non-selection sector voltage may be decided to have a voltage level sufficient to turn off a PMOS transistor.

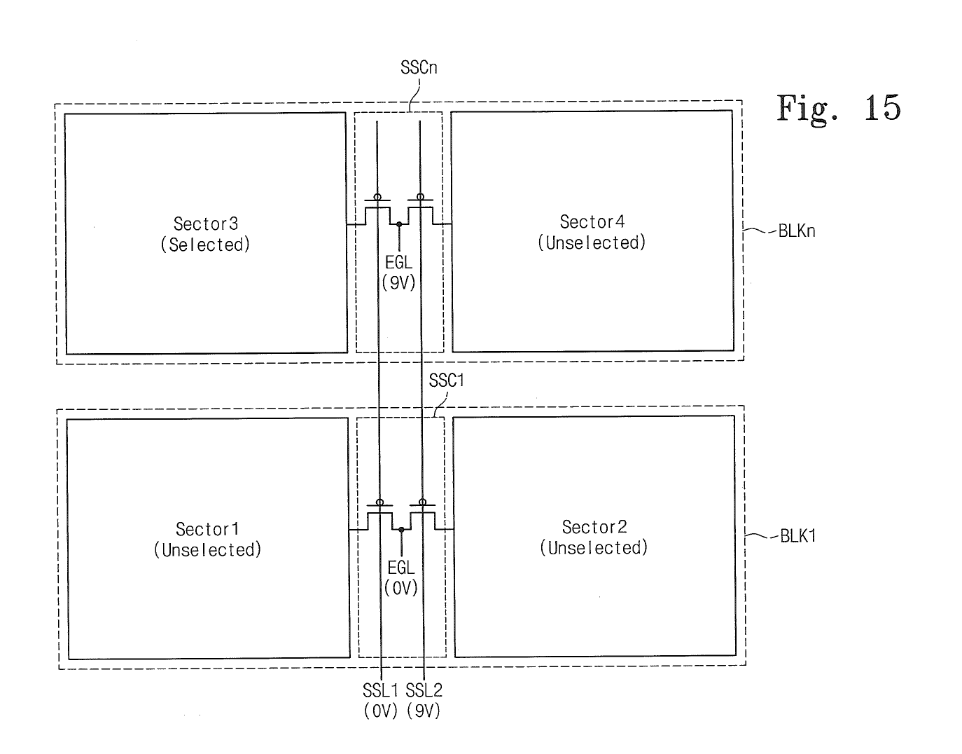

FIG. 15 is a diagram illustrating a sector to be erased according to a bias condition in FIG. 14. For ease of description, it is assumed that a third sector in an nth block BLKn is selected at an erase operation. With this assumption, an erase voltage of 9V may be provided to an erase gate line EGL of the nth block BLKn including the selected sector, and a voltage of 0V may be provided to the remaining blocks (e.g., a first block BLK1) other than the nth block BLKn. Also, the selection sector voltage of 0V may be applied to the first sector selecting line SSL1, and the non-selection sector voltage may be applied to the second sector selecting line SSL2. Thus, PMOS transistors connected to the first sector selecting line SSL1 may be turned on, and PMOS transistors connected to the second sector selecting line SSL2 may be turned off. In this case, since the erase voltage of 9V is provided to the erase gate line EGL of the nth block BLKn, the selected, that is, third sector may be erased. This may mean that an erase operation is performed by a sector unit.

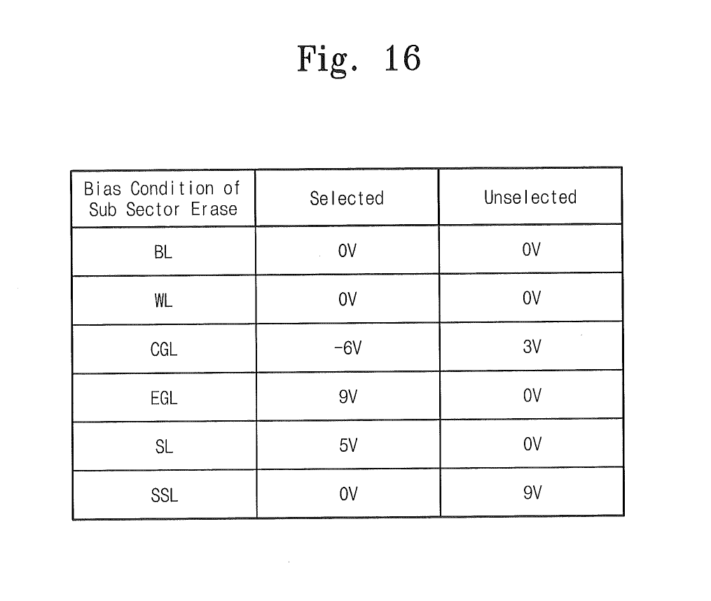

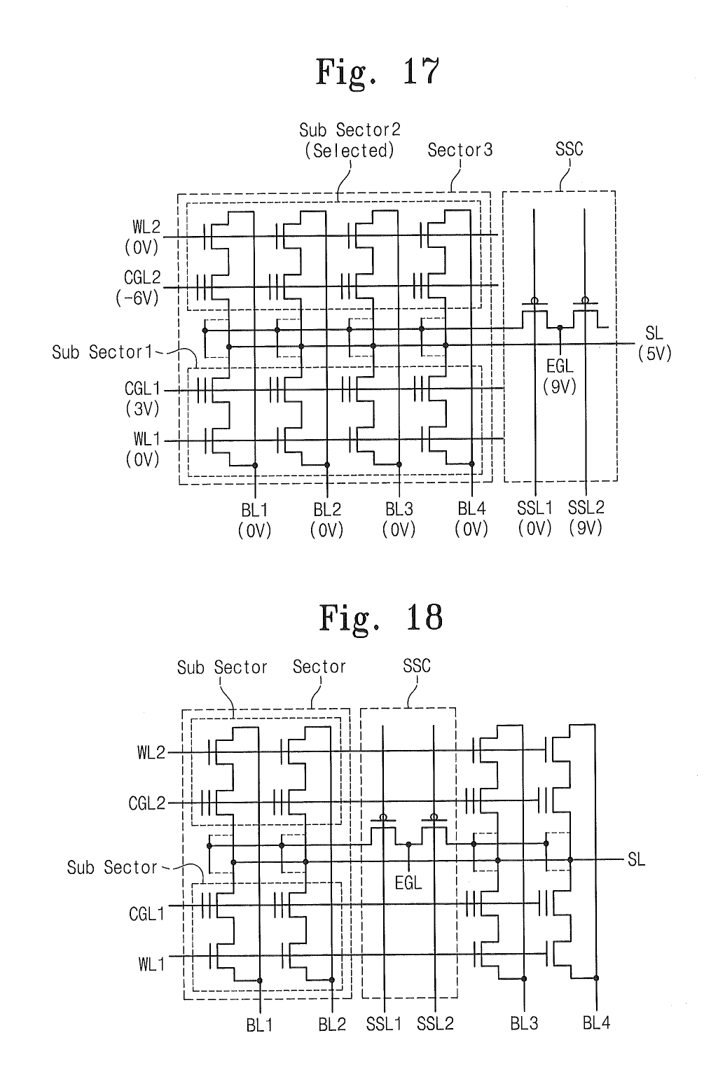

FIGS. 16 and 17 are diagrams describing an erase operation according to another embodiment of the inventive concept. An erase operation may be performed by a sub-sector unit. Herein, the sub-sector unit may be smaller than a sector unit, and may be formed of memory cells, connected to the same word line and control gate line, from among memory cells in a sector.

In FIG. 16, there is illustrated a bias condition of a memory cell array 110_1 in FIG. 13 when an erase operation is performed by a sub-sector unit. A bias condition in FIG. 16 may be similar to a bias condition performed by a page unit (refer to FIG. 10). Thus, a difference between a page erase operation and a sector erase operation will be focused.

As described in FIG. 13, a memory cell array 110_1 may further comprise a sector selecting circuit SSC and selector selecting lines connected to the sector selecting circuit SSC. A bias condition associated with a sector erase operation in FIG. 16 may further comprise a bias condition of a sector selecting line compared with a bias condition associated with a page erase operation in FIG. 10. When an erase operation is performed by a sub-sector unit, a selection sector voltage of 0V may be provided to a sector selecting line SSL corresponding to a selected sub-sector, and a non-selection sector voltage of 9V may be provided to a sector selecting line SSL corresponding to an unselected sub-sector.

In FIG. 17, there is illustrated a sub-sector to be erased according to a bias condition in FIG. 16. For ease of description, a sector including a selected sub-sector may be illustrated in FIG. 17. In example embodiments, it is assumed that a third sector includes first and second sub-sectors and the second sub-sector is erased.

In this case, a selection sector voltage of 0V may be provided to a first sector selecting line SSL1, and a non-selection sector voltage of 9V may be provided to a second sector selecting line SSL2. Thus, a PMOS transistor connected to the first sector selecting line SSL1 may be turned on, and an erase voltage of 9V may be applied to erase gates of the third sector via an erase gate line EGL.

A control gate erase voltage of −6V may be applied to a second control gate line CGL2 of the second sub-sector, and an erase-inhibit voltage of 3V may be applied to a first control gate line CGL1 of the first sub-sector. Thus, the first sub-sector may be erased.

As described above, a nonvolatile memory device according to an embodiment of the inventive concept may perform an erase operation by a sector unit or by a sub-sector unit using a sector selecting circuit SSC. Whether an erase operation is performed by a sector unit or by a sub-sector unit may be determined at a circuit design step by a designer.

FIG. 18 is a diagram schematically illustrating a memory cell array according to still another embodiment of the inventive concept. A memory cell array 110_2 in FIG. 18 may be similar to that 110_1 in FIG. 13. Thus, similar elements may be marked by similar reference numerals. For ease of description, elements constituting a sector may be illustrated in FIG. 18. Referring to FIG. 18, a sector selecting circuit SSC may be placed between two sectors. One sector may include two sub-sectors connected to different word lines and control gate lines. Each sub-sector may be connected to the same word line and control gate line. Each sub-sector may include two memory cells.

Returning to FIG. 13, each sector of a memory cell array 110_1 may include eight memory cells. Further, returning to FIG. 17, each sub-sector may include four memory cells. On the other hand, as illustrated in FIG. 18, a sector selecting circuit SSC may be placed between two bit line pairs, each sector may include four memory cells, and each sub-sector may include two memory cells. However, the inventive concept is not limited thereto. It is well understood that a sector selecting circuit SSC is disposed in various manners.

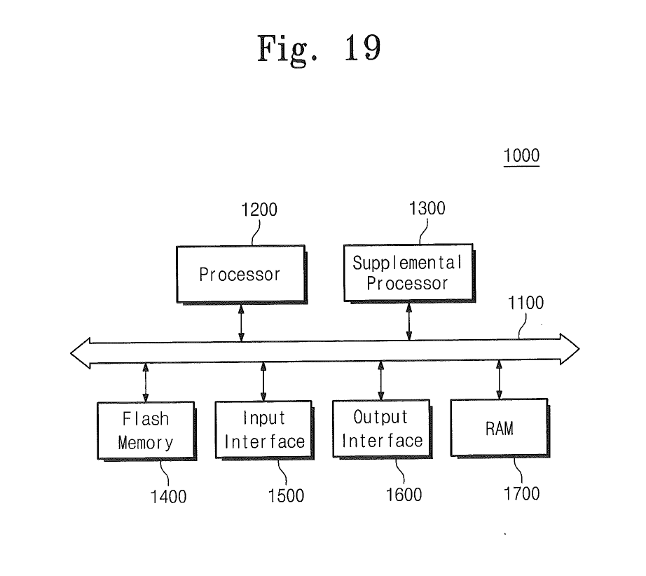

FIG. 19 is a block diagram schematically illustrating an embedded system according to an embodiment of the inventive concept. Referring to FIG. 19, an embedded system 1000 may include a system bus 1100, a processor 1200, a supplemental processor 1300, a flash memory 1400, an input interface 1500, an output interface 1600, and a RAM 1700. The system bus 1100 may provide channels between constituent elements of the embedded system 1000. The processor 1200 may control an overall operation of the embedded system 1000. The processor 1200 may include a general-purpose processor or an application processor (AP). The supplemental processor 1300 may be configured to supplement an operation of the processor 1200. The supplemental processor 1300 may include an image processor (or, codec), a sound processor (or, codec), a compression and decompression processor (or, codec), an encryption and decryption processor (or, codec), and the like. The flash memory 1400 may include a nonvolatile memory device 100 described with reference to FIGS. 1 to 18. The flash memory 1400 may have a structure described with reference to FIGS. 1 to 18, and may operate a program method.

The input interface 1500 may include devices receiving signals from an external device. The input interface 1500 may include at least one input device such as a button, a keyboard, a mouse, a microphone, a camera, a touch panel, a touch screen, a wire-wireless receiver, or the like. The output interface 1600 may include devices that enable the embedded system 1000 to transmit signals to the external device. The output interface 1600 may include at least one output device such as a monitor, a ramp, a speaker, a printer, a motor, a wire-wireless transmitter, or the like. The RAM 1700 may be a working memory of the embedded system 1000.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

1. An integrated circuit memory device, comprising:
an array of nonvolatile memory cells having a plurality of pairs of nonvolatile memory cells therein, said plurality of pairs of nonvolatile memory cells including a first pair of nonvolatile memory cells that share an erase gate electrode.

2. The memory device of claim 1, wherein each of the nonvolatile memory cells in the first pair of nonvolatile memory cells comprises a respective control gate electrode; and wherein the shared erase gate electrode extends between the control gate electrodes within the first pair of nonvolatile memory cells.

3. The memory device of claim 2, wherein each of the first pair of nonvolatile memory cells comprises a data storage transistor having a floating gate electrode therein and a selection transistor.

4. The memory device of claim 3, wherein the selection transistor and the data storage transistor within one of the first pair of nonvolatile memory cells are electrically connected in series; wherein a gate electrode of the selection transistor is electrically coupled to a respective word line; and wherein each of the data storage transistors within the first pair of nonvolatile memory cells comprises a respective one of the control gate electrodes.

5. The memory device of claim 4, wherein the shared erase gate electrode extends between the floating gate electrodes within the first pair of nonvolatile memory cells.

6. The memory device of claim 5, further comprising control logic configured to support a page erase operation by applying unequal voltages to the control gate electrodes of the first pair of nonvolatile memory cells to thereby selectively erase one of the first pair of nonvolatile memory cells, but not the other.

7. The memory device of claim 2, further comprising control logic configured to support a page erase operation by applying unequal voltages to the control gate electrodes of the first pair of nonvolatile memory cells to thereby selectively erase one of the first pair of nonvolatile memory cells, but not the other.

8. A nonvolatile memory device, comprising:
a block of nonvolatile memory cells having a plurality of pairs of nonvolatile memory cells therein, said plurality of pairs of nonvolatile memory cells including first pair of nonvolatile memory cells that share a first erase gate electrode within a first sector of said block and a second pair of nonvolatile memory cells that share a second erase gate electrode within a second sector of said block;
a sector selecting circuit electrically connected to the first and second erase gate electrodes, an erase gate line and first and second sector selection lines; and
control logic electrically coupled to said erase gate line and the first and second sector selection lines, said control logic configured to support a multi-sector page erase operation by driving the first and second sector selection lines with signals that cause said sector selecting circuit to electrically connect the first and second erase gate electrodes to the erase gate line and further configured to support a single-sector page erase operation by driving the first and second sector selection lines with signals that cause said sector selecting circuit to electrically connect the erase gate line one-at-a-time to the first and second erase gate electrodes.

9. The memory device of claim 8, wherein said sector selecting circuit comprises first and second PMOS transistors having first and second gate electrodes, respectively, electrically connected to the first and second sector selection lines, respectively.

10. The memory device of claim 8, wherein each of the nonvolatile memory cells in the first pair of nonvolatile memory cells comprises a respective control gate electrode; and wherein the shared first erase gate electrode extends between the control gate electrodes within the first pair of nonvolatile memory cells.

11. The memory device of claim 10, wherein each of the nonvolatile memory cells in the first pair of nonvolatile memory cells comprises a data storage transistor having a floating gate electrode therein and a selection transistor.

12. The memory device of claim 11, wherein the selection transistor and the data storage transistor within one of the first pair of nonvolatile memory cells are electrically connected in series; wherein a gate electrode of the selection transistor is electrically coupled to a respective word line; and wherein each of the data storage transistors within the first pair of nonvolatile memory cells comprises a respective one of the control gate electrodes.

13. A nonvolatile memory device comprising:
a memory cell array including a plurality of memory cells each having a cell transistor and a selection transistor, two adjacent memory cells of the plurality of memory cells sharing an erase gate; and
control logic configured to control the memory cell array;
wherein during an erase operation, the control logic applies different voltages to a control gate of a selected memory cell and a control gate of an unselected memory cell to perform an erase operation by a page unit.

14. The nonvolatile memory device of claim 13, wherein a first voltage is provided to the control gate of the selected memory cell, a second voltage higher than the first voltage is provided to the control gate of the unselected memory cell, and an erase voltage higher than the second voltage is provided to the erase gate.

15. The nonvolatile memory device of claim 14, wherein a potential difference between the first voltage and the erase voltage is larger than a predetermined potential different such that electrons are shifted into the erase gate from a floating gate of the selected memory cell.

16. The nonvolatile memory device of claim 14, wherein a potential difference between the second voltage and the erase voltage is smaller than a predetermined potential different such that electrons are shifted into the erase gate from a floating gate of the selected memory cell.

17. The nonvolatile memory device of claim 13, wherein the plurality of memory cells forms a first sector and a second sector, and the memory cell array further includes a sector selecting circuit placed between the first sector and the second sector.

18. The nonvolatile memory device of claim 17, wherein each of the first and second sectors includes at least two memory cells connected in series and an erase gate placed between the at least two memory cells, and the sector selecting circuit includes first and second transistors placed between an erase gate of the first sector and an erase gate of the second sector.

19. The nonvolatile memory device of claim 18, wherein the first transistor transfers an erase voltage to the erase gate of the first sector in response to a first sector selecting voltage, and the second transistor transfers the erase voltage to the erase gate of the second sector in response to a second sector selecting voltage, the first and second transistors being selectively turned on at an erase operation.

20. The nonvolatile memory device of claim 13, wherein the plurality of memory cells forms a first sector and a second sector, each of the first and second sectors includes at least two sub-sectors and an erase gate placed between the at least two sub-sectors, the at least two sub-sectors including at least two memory cells connected via the same word line and the same control gate line; and
wherein the memory cell array further includes a selection circuit placed between the first sector and the second sector.

21.-27. (canceled)
